(19) United States
(12) Patent Application Publication
(10) Pub. No.: US 2025/0056816 A1
(43) Pub. Date: Feb. 13, 2025

(54) MEMORY DEVICE

(71) Applicant: MACRONIX International Co., Ltd., Hsinchu (TW)

(72) Inventors: Yung-Hsiang Chen, Taipei City (TW); I-Chen Yang, Miaoli County (TW); Hsing-Wen Chang, Miaoli County (TW); Yao-Wen Chang, Hsinchu County (TW)

(73) Assignee: MACRONIX International Co., Ltd., Hsinchu (TW)

(21) Appl. No.: 18/780,515

(22) Filed: Jul. 23, 2024

Related U.S. Application Data
(60) Provisional application No. 63/532,056, filed on Aug. 10, 2023.

(51) Int. Cl. H10B 80/00; H01L 25/065; H01L 25/18

(52) U.S. Cl. CPC H10B 80/00; H01L 25/0657; H01L 25/18; H01L 2225/06541

(57) ABSTRACT

A memory device includes a plurality of first peripheral circuits, a stack memory cell array and a first address circuit. The first peripheral circuits are disposed on a first chip, wherein the first chip has a plurality of first pads. The stack memory cell array is disposed on a second chip, wherein the second chip has a plurality of second pads. The second pads are coupled to the stack memory cell array, and respectively coupled to corresponding first pads. The first address circuit is disposed on the second chip, coupled to the stack memory cell array, and disposed under the stack memory cell array.

### CROSS-REFERENCE TO RELATED APPLICATION

This application claims the priority benefits of U.S. provisional application Ser. No. 63/532,056, filed on Aug. 10, 2023. The entirety of the above-mentioned patent application is hereby incorporated by reference herein.

### BACKGROUND

### Technical Field

The disclosure relates to a memory device, and in particular relates to a memory device constructed by stacking multiple chips.

### Description of Related Art

With the increase of the memory capacity requirement of a memory device, the stacking levels of the memory cell array in the stack memory device, the corresponding address circuit, and the number of transistors in the peripheral circuit also increase rapidly. In this way, the practice of accommodating a complete memory device through a single chip in prior art results in the chip size being insufficient to accommodate an excessive number of transistors. A technique used to implement peripheral circuits in stacked memory devices is known as CMOS-under-array (CuA) process. This can conserve area on the chip. On the other hand, the array process can involve relatively high temperatures and otherwise carry a significant thermal budget which can impact the underlying circuits.

On the other hand, as the stacking level of the memory cell array increases, the access rate of the memory device must also increase accordingly. However, some advanced process materials and structures necessary for compact and reliable high speed peripheral circuits, cannot be applied in a CuA process, because these advanced process materials and structures may be damaged by the thermal budget that arise during array formation. Therefore, in prior art, the access rate of the memory device cannot be effectively improved.

### SUMMARY

A memory device, which may effectively improve access efficiency, is provided in the disclosure.

The memory device of the disclosure includes multiple first peripheral circuits, a stack memory cell array, and a first address circuit. The first peripheral circuits are disposed on a first chip, in which the first chip has multiple first pads. The stack memory cell array is disposed on a second chip, in which the second chip has multiple second pads. The second pads are coupled to the stack memory cell array, and respectively coupled to corresponding first pads. The first address circuit is disposed on the second chip, coupled to the stack memory cell array, and disposed under the stack memory cell array.

The memory device of the disclosure includes a first chip and a second chip. The first chip includes a plurality of first peripheral circuits and a plurality of first pads, and the first pads forming on a surface of the first chip. The second chip includes a stack memory cell array, a first address circuit and a plurality of second pads. The first address circuit is coupled to the stack memory cell array, and disposed under the stack memory cell array. The second pads are formed on a surface of the second chip, and are respectively coupled to the first pads. Wherein, thermal budgets of the first chip and the second chip are different.

Based on the above, in the disclosure, the peripheral circuits of the memory device are disposed on the first chip, and the stack memory cell array is disposed on the second chip. The second chip may be applied in a CMOS (complementary metal oxide semiconductor)-under-array (CuA) process, while the first chip may be applied in a process with a relatively low thermal budget. In this way, the electrical characteristics of the peripheral circuits on the first chip may be effectively improved, thereby improving the access performance of the memory device. The issue that the chip is exposed to the array manufacturing process, which can involve temperatures that can damage the chip. In this embodiment, by using separate wafers enables the best available chip without exposure to array manufacturing, and the issue can be solved.

### BRIEF DESCRIPTION OF THE DRAWINGS

FIG. 1 is a cross-sectional schematic diagram illustrating the structure of a memory device according to an embodiment of the disclosure.

FIG. 2A and FIG. 2B are cross-sectional schematic diagrams respectively illustrating the structure of the transistor in the first chip and the second chip of the memory device in the embodiment of the disclosure.

FIG. 3A and FIG. 3B are respectively schematic diagrams illustrating the change in electrical characteristics of the transistor in the first chip before and after adding silicide structures in the memory device according to the embodiment of the disclosure.

FIG. 4 is a cross-sectional schematic diagram illustrating the structure of a memory device according to another embodiment of the disclosure.

FIG. 5 is a cross-sectional schematic diagram illustrating the structure of a memory device according to another embodiment of the disclosure.

FIG. 6 is a cross-sectional schematic diagram illustrating the structure of a memory device according to another embodiment of the disclosure.

FIG. 7 is a block diagram of a memory device according to an embodiment of present invention.

### DETAILED DESCRIPTION OF DISCLOSED EMBODIMENTS

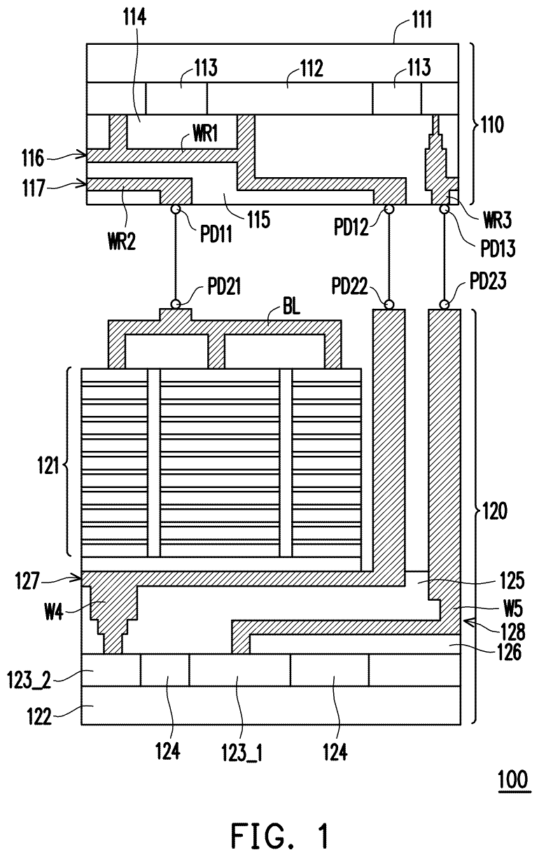

Referring to FIG. 1, FIG. 1 is a cross-sectional schematic diagram illustrating the structure of a memory device according to an embodiment of the disclosure. The memory device 100 includes peripheral circuits, a stack memory cell array 121, and an address circuit. The peripheral circuits are disposed in the first chip 110, and the stack memory cell array 121 and the address circuit are disposed in the second chip 120. In this embodiment, the first chip 110 has a substrate 111, a transistor structure 112, a shallow trench isolation structure 113, metal layers 116 and 117, and dielectric layers 114 and 115. The transistor structure 112 is formed on the substrate 111 and configured to form peripheral circuits. The shallow trench isolation structure 113 is formed on the substrate 111 and on two sides of the transistor structure 112. The metal layers 116 and 117 and the dielectric layers 114 and 115 are alternately disposed, and the metal layers 116 and 117 are configured to form multiple transmission wires WR1 to WR3 for transmitting power or signal between the first chip 110 and the second chip 120. Multiple pads PD11 to PD13 may be formed on the surface of the first chip 110. The terminals of the transmission wires WR1 to WR3 are respectively coupled to the pads PD11 to PD13. The other terminals of the transmission wires WR1 to WR3 may be coupled to multiple transistor structures in the first chip 110 (e.g., the transmission wire WR1 is coupled to the pad PD12).

In this embodiment, the dielectric layer 114 may be an interlayer dielectric (ILD), and the dielectric layer 115 may be an inter-metal dielectric (IMD). In this embodiment, the ILD is referred to a dielectric disposed between a silicon layer and a metal layer, and the IMD is referred to a dielectric disposed between two metal layers.

On the other hand, the second chip 120 has a stack memory cell array 121, a substrate 122, and circuits below the stack memory cell array 121 including representative transistor structures 123_1 and 123_2, with for example a shallow trench isolation structure 124, metal layers 127 and 128, and dielectric layers 125 and 126. The transistor structure 123 is formed on the substrate 122 in this embodiment is part of an address circuit. The address circuit may be configured to generate address signals such as word line signals. The shallow trench isolation structure 124 is formed on the substrate 122 and on the sides of the transistor structures 123_1 and 123_2. The metal layers 127 and 128 and the dielectric layers 125 and 126 are alternately disposed, and the metal layers 127 and 128 are configured to form multiple transmission wires WR4 and WR5. The transmission wire WR4 is connected between the transistor structure 123_2 and the stack memory cell array 121, and may be coupled to the pad PD22. The transmission wire WR5 is connected between the transistor structure 123_1 and the pad PD23.

In this embodiment, the dielectric layer 126 may be an interlayer dielectric (ILD), and the dielectric layer 125 may be an inter-metal dielectric (IMD).

Multiple pads PD21 to PD23 are formed on the surface of the second chip 120. The pads PD21 to PD23 on the second chip 120 are configured to respectively electrically connect with the pads PD11 to PD13 on the surface of the first chip 110. In the second chip 120, bit lines BL may be formed on the stack memory cell array 121. The bit line BL may be coupled to the pad PD21 and between memory cells in the stack memory cell array 121.

In this embodiment, the first chip 110 may be respectively electrically connected to the pads PD21 to PD23 of the second chip 120 through the pads PD11 to PD13. The bit line BL of the stack memory cell array 121 in the second chip 120 may be coupled to the peripheral circuit in the first chip 110 so that the memory device 100 may have a complete structure. In this embodiment, the peripheral circuits in the first chip 110 include multiple page buffers, multiple address decoding circuits, and multiple input and output circuits. To be specific, in the memory device recognized by those skilled in the art, any circuit in the back end of the bit line outside of the memory cell array may be disposed in the peripheral circuits of the embodiment of the disclosure, without special limitation. The address circuit in the second chip 120 may be a word line decoder and related circuits in a memory device.

It is worth mentioning that in this embodiment, in the memory device 100, the peripheral circuits of the bit line BL segment are disposed in the first chip 110, and the stack memory cell array 121 and the corresponding address circuit are disposed in the second chip 120. In this way, the first chip 110 is not limited to be applied to the CMOS-under-array (CuA) process, but may adopt materials with relatively low temperature resistance, which may effectively improve the electrical characteristics of the peripheral circuits in the first chip 110, and improve the working performance of the memory device 100.

Incidentally, in the embodiment of the disclosure, the transmission wires WR4 and WR3 may also be used for power transmission.

In this embodiment, in the first chip 110, the material of the metal layers 116 and 117 configured to form the transmission wires WR1 to WR3 may be copper or aluminum or other metals or alloys having low resistivity (smaller than 3×10⁻⁶ Ω-cm) and lower melting temperatures (smaller than 400° C.), and the dielectric coefficients of the dielectric layers 114 and 115 in the first chip 110 may be less than a threshold, for example, the dielectric layers 114 and 115 may be constructed with materials with a dielectric constant k<3.0, such as Parylene-N (k=2.7), B-staged Polymers (k=2.6-2.7) or Parylene-F (k=2.4-2.5). Since the transistor structure 112 in the first chip 110 is not required to withstand relatively high stress, the dielectric layers 114 and 115 may be implemented with a material with a low dielectric coefficient. In contrast, in the second chip 120, the material of the metal layers 127 and 128 configured to form the transmission wires WR4 and WR5 may be the same as the metal used in the array structure, such as tungsten which has higher melting temperatures greater than 1000° C. and high resistivities, such as >than 5×10⁻⁶ Ω-cm.

In this embodiment, the stack memory cell array 121 may be any form of stack memory cell array, such as a three-dimensional AND type, NOR type, or NAND type flash memory cell array, there is no certain limitation.

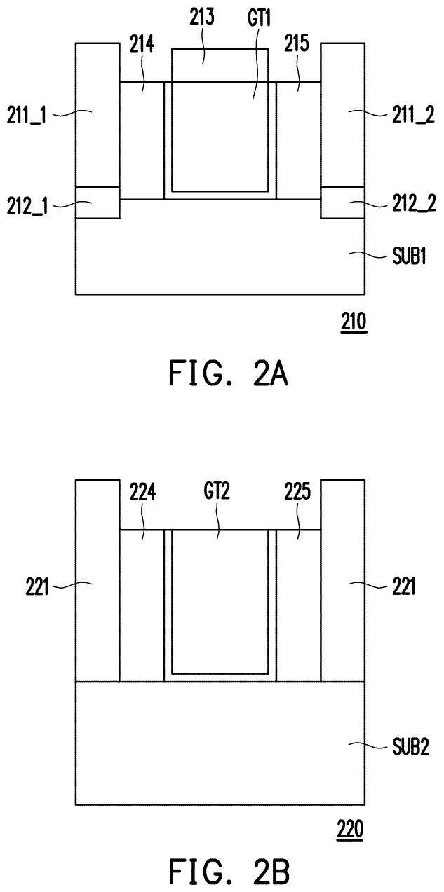

Referring to FIG. 2A and FIG. 2B below, FIG. 2A and FIG. 2B are cross-sectional schematic diagrams respectively illustrating a transistor structure 210 suitable for use as a transistor in the first chip and a transistor structure 220 suitable for use as a transistor in the second chip of the memory device in the embodiment of the disclosure. In FIG. 2A, the transistor structure 210 disposed in the first chip includes a substrate SUB1, a gate structure GT1, a source structure 214, a drain structure 215, multiple silicide structures 212_1 and 212_2, and multiple conductive structures 211_1 and 211_2. The source structure 214 and the drain structure 215 are respectively formed on two sides of the substrate SUB1, and the gate structure GT1 may be formed between the source structure 214 and the drain structure 215. The two silicide structures 212_1 and 212_2 may be respectively formed on the substrate SUB, and respectively formed in the source structure 214 and the drain structure 215. The conductive structures 211_1 and 211_2 are respectively formed on the silicide structures 212_1 and 212_2. The conductive structure 211_1 and the silicide structure 212_1 may form a contact, and the conductive structure 211_2 and the silicide structure 212_2 may form another contact.

Please note that in this embodiment, by respectively disposing the silicide structures 212_1 and 212_2 between the conductive structures 211_1, 211_2 and the substrate SUB1, the contact resistance provided by the formed contacts may be effectively reduced, and the signal transmission performance may be improved. In this embodiment, the silicide structures 212_1 and 212_2 may be nickel silicide structures or cobalt silicide structures. The material of the conductive structures 211_1 and 211_2 may be tungsten.

The temperature resistance of the nickel silicide structure is less than 800 degrees Celsius, and the temperature resistance of the cobalt silicide structure is less than 900 degrees Celsius. That is, the temperature resistance of the silicide structures 212_1 and 212_2 of the embodiment of the disclosure is less than the temperature resistance of the conductive structures 211_1 and 211_2.

Incidentally, the silicide structure 213 may be disposed on the gate structure GT1 of the transistor 210 and electrically connected to the gate structure GT1. In this embodiment, the silicide structures 212_1 and 212_2 may have same material.

In FIG. 2B, the transistor 220 disposed in the second chip includes a substrate SUB2, a gate structure GT2, a source structure 224, a drain structure 225, and multiple conductive structures 221_1 and 221_2.

The source structure 224 and the drain structure 225 are respectively formed on two sides of the substrate SUB2, and the gate structure GT2 may be formed between the source structure 224 and the drain structure 225. The conductive structures 221_1 and 221_2 are formed on the substrate SUB2, and are respectively formed in the source structure 224 and the drain structure 225, and two contacts are respectively formed.

Different from the embodiment in FIG. 2A, the transistor 220 disposed in the second chip may not be provided with a silicide structure, so it is suitable for a CMOS-under-array (CuA) process.

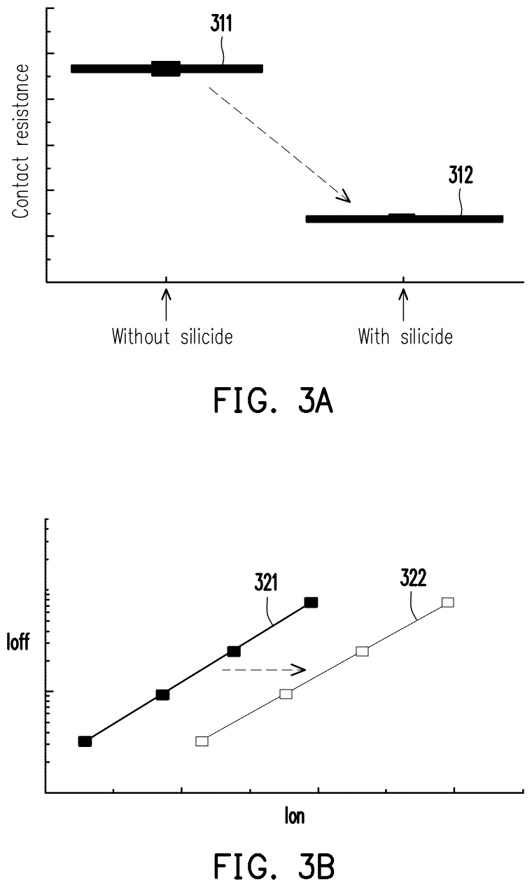

Referring to FIG. 3A and FIG. 3B below, FIG. 3A and FIG. 3B are respectively schematic diagrams illustrating the change in electrical characteristics of the transistor in the first chip before and after adding silicide structures in the memory device according to the embodiment of the disclosure. In FIG. 3A, the vertical axis is the resistance value of the contact resistance of the contact in the transistor. The line segment 311 corresponding to one side of the horizontal axis is the case of no added silicide structure in the contact, and the line segment 312 corresponding to the other side of the horizontal axis is the case of added silicide structure in the contact. It may be seen that, in the embodiment of the disclosure, when the silicide structure is added in the contact, the contact resistance of the contact may be effectively reduced, and the transmission efficiency of signals and/or power may be improved.

In FIG. 3B, the vertical axis is the off-current Ioff when the transistor is turned off, and the horizontal axis is the on-current Ion when the transistor is turned on. The straight line 321 represents the case of no added silicide structure in the contact of the transistor, and the straight line 322 represents the case of added silicide structure in the contact of the transistor. When there is silicide structure added in the contact of the transistor, compared with the straight line 321, the straight line 322 formed by the relationship of the on-current Ion and the off-current Ioff shifts towards the direction of relatively high on-current. Therefore, the current transmission performance of the transistor is significantly improved.

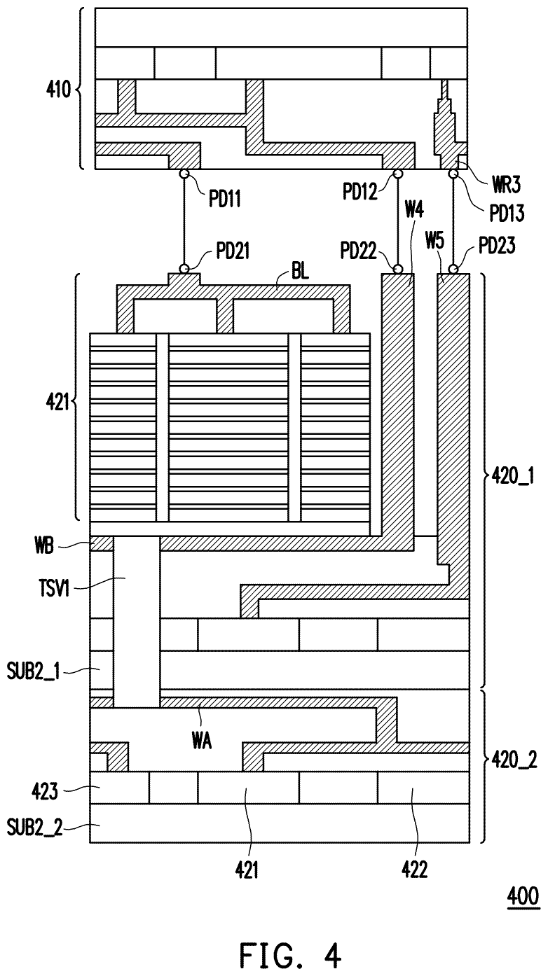

Referring to FIG. 4, FIG. 4 is a cross-sectional schematic diagram illustrating the structure of a memory device according to another embodiment of the disclosure. The memory device 400 is formed by a first chip 410, a second chip 420_1, and a third chip 420_2. The first chip 410 has multiple transistors to form peripheral circuits. The implementation details of the first chip 410 have already been described in the foregoing embodiments, and are not repeated herein.

The second chip 420_1 includes a stack memory cell array 421. The bit line BL on the stack memory cell array 421 may be coupled to the pad PD11 formed on the first chip 410 through the pad PD21 formed on the second chip 420_1. On the other hand, the transmission wires W4 and W5 on the second chip 420_1 may be respectively coupled to the pads PD12 and PD13 formed on the first chip 410 through the pads PD22 and PD23 formed on the second chip 420_1. The second chip 420_1 further includes an address circuit, in which the address circuit is disposed under the stack memory cell array 421. The implementation details of the second chip 420 have already been described in the foregoing embodiments, and are not repeated herein.

Different from the foregoing embodiments, the memory device 400 further has a third chip 420_2. The third chip 420_2 is disposed under the second chip 420_1 and is stacked with the second chip 420_1. The third chip 420_2 includes multiple transistor structures 421 to 423. The transistor structures 421 to 423 in the third chip 420_2 may be configured to form the address circuit of the stack memory cell array 421. That is, in this embodiment, the address circuit of the stack memory cell array 421 may be distributed in the second chip 420_1 and the third chip 420_2, thereby increasing the number of transistors for disposing. Of course, any peripheral circuits other than the address circuit may also be provided in the third chip 420_2, and there is no specific limitation.

The third chip 420_2 may also have multiple metal layers to form multiple transmission wires, such as the transmission wire WA. The second chip 420_1 and the third chip 420_2 may respectively have substrates SUB2_1 and SUB2_2.

In another embodiment, between the second chip 420_1 and the third chip 420_2, through-silicon vias (TSVs) may be formed in between to communicate electrical signals, where each of the electrical signal includes power, control voltage, control current, bias voltage or bias current. In this embodiment, the transmission wire WB in the second chip 420_1 and the transmission wire WA in the third chip 420_2 may be electrically connected to each other through the through-silicon via TSV1. The second chip 420_1 and the third chip 420_2 may transmit signals or power through the through-silicon via TSV1.

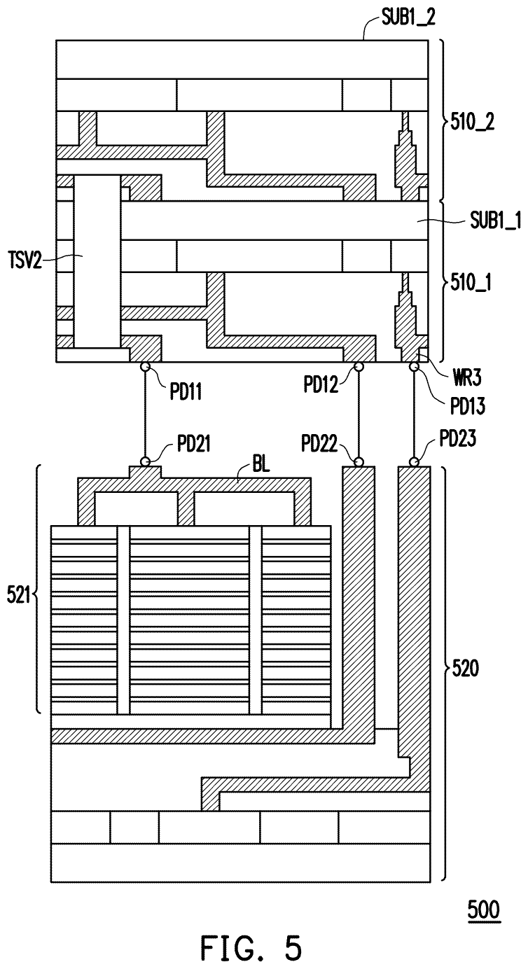

Referring to FIG. 5, FIG. 5 is a cross-sectional schematic diagram illustrating the structure of a memory device according to another embodiment of the disclosure. The memory device 500 is formed by a first chip 510_1, a second chip 520, and a third chip 510_2. The first chip 510_1 and the third chip 510_2 are stacked on each other. The first chip 510_1 and the third chip 510_2 may be respectively configured for disposing peripheral circuits. In this way, the number of transistors in the peripheral circuits of the memory device 500 may be effectively increased. Of course, other circuits other than peripheral circuits may also be provided in the third chip 510_2, without any special limitation.

In this embodiment, the first chip 510_1 and the third chip 510_2 may have a similar structure, and the first chip 510_1 and the third chip 510_2 respectively has a substrate SUB1_1 and a SUB1_2.

Moreover, similar to the embodiment in FIG. 4, the first chip 510_1 and the third chip 510_2 may communicate power and signals through the through-silicon via TSV2. Of course, the number of the through-silicon via TSV2 may be one or more, and the illustration in FIG. 5 is only an example for illustration and is not intended to limit the scope of the disclosure.

In addition, multiple pads PD11 to PD13 are formed on the first chip 510_1, and are respectively electrically connected to multiple pads PD21 to PD23 on the second chip 520. A stack memory cell array 521 is formed on the second chip 520.

The implementation details of the first chip 510_1 and the second chip 520 have already been described in the foregoing embodiments, and are not repeated herein.

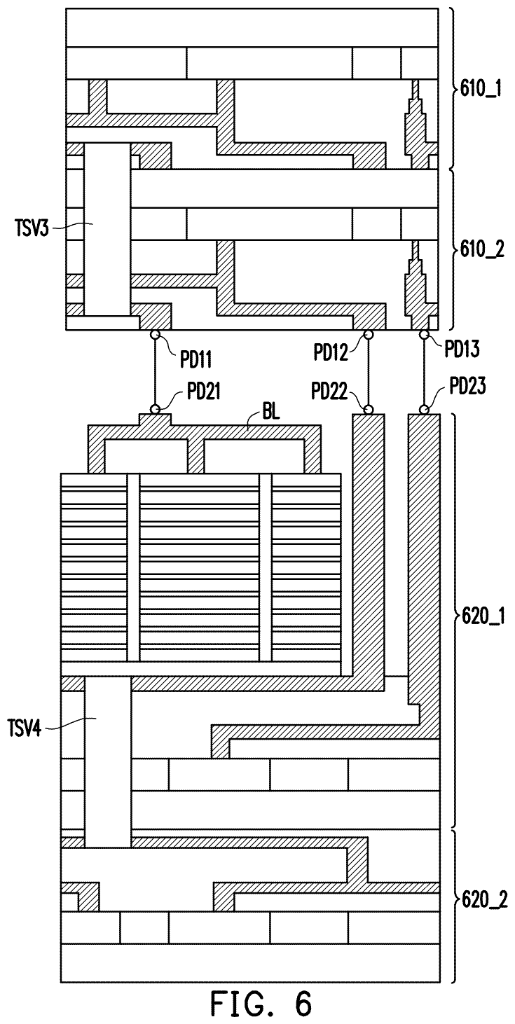

Referring to FIG. 6, FIG. 6 is a cross-sectional schematic diagram illustrating the structure of a memory device according to another embodiment of the disclosure. The memory device 600 is formed by a first chip 610_1, a second chip 620_1, a third chip 610_2, and a third chip 620_2. The first chip 610_1 and the third chip 610_2 are stacked on each other, and the second chip 620_1 and the third chip 620_2 are stacked on each other. The first chip 610_1 and the third chip 610_2 may transmit power or signals between each other through the through-silicon via TSV3. The second chip 620_1 and the third chip 620_2 may transmit power or signals between each other through the through-silicon via TSV4. The first chip 610_1 and the second chip 620_1 are electrically connected to each other through a wafer bonding process through respectively formed pads PD11 to PD13, PD21 to PD23.

The implementation methods of the first chip 610_1, the second chip 620_1, the third chip 610_2 and the third chip 620_2 have been described in detail in the foregoing embodiments, and are not repeated herein.

It is worth mentioning that, in the embodiment of the disclosure, the number of layers of the third chip 610_2 stacked with the first chip 610_1 may be one or more, and there is no certain limitation. The number of layers of the third chip 620_2 stacked with the second chip 620_1 may also be one or more, and there is also no certain limitation.

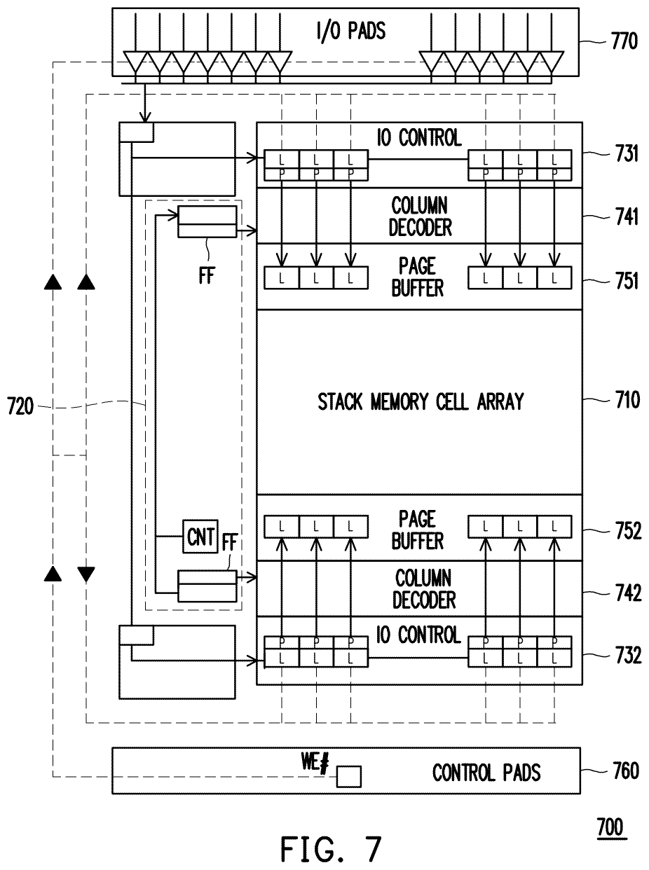

Please refer to FIG. 7. FIG. 7 is a block diagram of a memory device according to an embodiment of present invention. The memory device 700 includes a stack memory cell array 710, an address circuit 720, IO controllers 731, 732, column decoders 741, 742, page buffers 751, 752, control pads 760 and I/O pads 770. In present embodiment, the IO controllers 731, 732, the column decoders 741, 742 and page buffers 751, 752 are peripheral circuits and are disposed on a first chip. The stack memory cell array 710 and the address circuit 720 are disposed in the second chip. A process temperature of the first chip is different from the process temperature of the second chip. For example, the process temperature of the first chip is lower than the process temperature of the second chip. Each of the IO controllers 731 and 732 has a plurality of latches L and write-in pulse generators P. The write-in pulse generators P is used to perform data write-in operation on corresponding page buffers 751 and 752.

Besides, the address circuit 720 has a plurality of flip-flops FF. The flip-flops FF are used to transmit address information to the column decoders 741 and 742.

It can be known by aforementioned embodiments, the page buffers 751 and 752 of present embodiment may be coupled to pads on the second chip through pads on the first chip, and further coupled to the stack memory cell array 710 through the pads on the second chip. Similarly, the address circuit 720 may be coupled to the corresponding pads on the first chip through the pads on the second chip, to transmit the address information to the column decoder 741 and 742.

Besides, in present embodiment, the control pads 760 may receive a write-in control signal WE #, and transmit the write-in control signal WE # to the I/O pads 770.

In addition, regarding the memory devices 400 to 600 of the above-mentioned embodiments, the first chip does not necessarily have to be disposed above the second chip, and the upper and lower positions of the chips may be adjusted arbitrarily without specific limitations.

To sum up, in the disclosure, the peripheral circuits of the memory device are disposed in the first chip, and the stack memory cell array and the first address circuit are disposed in the second chip. The first chip and the second chip are electrically connected to each other through a wafer bonding process to form a complete memory device. Therefore, the peripheral circuits in the first chip may be applied to a process with a relatively low-temperature, and semiconductor materials with relatively low temperature resistance may be used to form the transistor structure therein. In this way, the electrical characteristics of the peripheral circuits may be effectively improved, thereby improving the working performance of the memory device.

What is claimed is:

1. A memory device, comprising:
a plurality of first peripheral circuits, disposed on a first chip, wherein the first chip has a plurality of first pads;
a stack memory cell array, disposed on a second chip, wherein a plurality of second pads are formed on the second chip, the second pads are coupled to the stack memory cell array and respectively coupled to the corresponding first pads; and
a first address circuit, disposed on the second chip, coupled to the stack memory cell array, and disposed under the stack memory cell array.

2. The memory device according to claim 1, wherein the first chip comprises a plurality of transistors, each of the transistors comprises:
a substrate;
a gate structure, disposed on the substrate;
a source structure and a drain structure, formed on the substrate;
a plurality of silicide structures, formed on the substrate, and respectively formed in the source structure and the drain structure; and
a plurality of conductive structures, respectively forming on the silicide structures to form a plurality of contacts.

3. The memory device according to claim 2, wherein temperature resistance of each of the silicide structures is less than temperature resistance of each of the conductive structures.

4. The memory device according to claim 2, wherein each of the silicide structures is a nickel silicide structure or a cobalt silicide structure, wherein a material of each of the conductive structures is tungsten.

5. The memory device according to claim 2, wherein the first chip further comprises:
a plurality of metal layers, configured to form a plurality of transmission wires so that each of the first pads is coupled to each of the corresponding contacts; and
a plurality of dielectric layers, disposed alternately with the metal layers.

6. The memory device according to claim 5, wherein a material of the metal layers are copper or aluminum, and a dielectric coefficient of the dielectric layers is less than a threshold.

7. The memory device according to claim 1, wherein the second pads are respectively coupled to a plurality of bit lines on the stack memory cell array.

8. The memory device according to claim 7, wherein the peripheral circuits comprise:
a plurality of page buffers, respectively coupled to the first pads, each of the page buffers is coupled to each of the corresponding bit lines through each of the corresponding first pads and each of the corresponding second pads.

9. The memory device according to claim 8, wherein the peripheral circuits further comprise:
a plurality of address decoding circuits and a plurality of input and output circuits, wherein the address decoding circuits are respectively coupled to the page buffers, and the page buffers are respectively coupled to the input and output circuits.

10. The memory device according to claim 1, further comprising:
a plurality of power transmission wires formed in the second chip, and the power transmission wires are respectively coupled to a plurality of third pads on the second chip,
the third pads are respectively coupled to the plurality of fourth pads on the first chip, and are used for power transmission between the first chip and the second chip.

11. The memory device according to claim 1, further comprising:
a plurality of second peripheral circuits, disposed in at least one third chip, wherein the at least one third chip and the first chip are stacked on each other, wherein at least one first transmission wire in the first chip is coupled to at least one second transmission wire in the at least one third chip through at least one through-silicon via.

12. The memory device according to claim 1, further comprising:
a plurality of second address circuits, disposed in at least one third chip, wherein the at least one third chip and the second chip are stacked on each other, wherein, at least one first transmission wire in the second chip is coupled to at least one second transmission wire in the at least one third chip through at least one through-silicon via.

13. The memory device according to claim 1, wherein the second chip comprises a plurality of transistors, each of the transistors comprises:
a substrate;
a gate structure, disposed on the substrate;
a source structure and a drain structure, formed on the substrate; and
a plurality of conductive structures, respectively forming on the source structure and the drain structure, and forming a plurality of contacts.

14. The memory device according to claim 1, wherein the stack memory cell array is a three-dimensional AND type, NAND type, or NOR type memory cell array.

15. The memory device according to claim 1, wherein a material of a plurality of transmission wires in the second chip is tungsten.

16. A memory device, comprising:
a first chip, comprising a plurality of first peripheral circuits and a plurality of first pads, and the first pads forming on a surface of the first chip;
a second chip, comprising:
a stack memory cell array;
a first address circuit, coupled to the stack memory cell array, and disposed under the stack memory cell array; and
a plurality of second pads, formed on a surface of the second chip, and respectively coupled to the first pads,
wherein process temperatures of the first chip and the second chip are different.

17. The memory device according to claim 16, wherein the process temperature of the first chip is lower than the process temperature of the second chip.

18. The memory device according to claim 16, wherein the first chip comprises a plurality of transistors, each of the transistors comprises:
a substrate;
a gate structure, disposed on the substrate;
a source structure and a drain structure, formed on the substrate;
a plurality of silicide structures, formed on the substrate, and respectively formed in the source structure and the drain structure; and
a plurality of conductive structures, respectively forming on the silicide structures to form a plurality of contacts.

19. The memory device according to claim 16, further comprising:
at least one third chip, stacked with the first chip, wherein the at least one third chip comprises a plurality of second peripheral circuits, at least one first transmission wire in the first chip is coupled to at least one second transmission wire in the at least one third chip through at least one through-silicon via.

20. The memory device according to claim 16, further comprising:
at least one third chip, stacked with the second chip, wherein the at least one third chip comprises a plurality of second address circuits, at least one first transmission wire in the second chip is coupled to at least one second transmission wire in the at least one third chip through at least one through-silicon via.
